(19) United States
(12) Patent Application Publication
(10) Pub. No.: US 2010/0077610 A1
(43) Pub. Date: Apr. 1, 2010

(54) METHOD FOR MANUFACTURING THREE-DIMENSIONAL CIRCUIT

(75) Inventors: Tzyy-Jang Tseng, Hsinchu City (TW); Cheng-Po Yu, Taoyuan County (TW)

Correspondence Address: J C PATENTS, 4 VENTURE, SUITE 250, IRVINE, CA, 92618, US

(73) Assignee: UNIMICRON TECHNOLOGY CORP., Taoyuan (TW)

(21) Appl. No.: 12/243,211

(22) Filed: Oct. 1, 2008

(51) Int. Cl. H05K 3/10

(52) U.S. Cl. 29/846

(57) ABSTRACT

A method for manufacturing a three-dimensional circuit is described as follows. Firstly, a three-dimensional insulating structure having at least one uneven surface is provided. Secondly, a self-assembly film is formed on the uneven surface for completely covering the uneven surface. Next, a catalytic film is formed on the self-assembly film. Afterward, the self-assembly film and the catalytic film are patterned. Then, a three-dimensional circuit structure is formed on the catalytic film by chemical deposition.

### BACKGROUND OF THE INVENTION

1. Field of the Invention

The present invention relates to a method for manufacturing a circuit, and more particularly to a method for manufacturing a three-dimensional circuit.

2. Description of Related Art

In recent years, as electronic techniques develop rapidly and hi-tech electronic industries come into being in succession, more humanized electronic products with better functions are continuously progressing and advancing to obtain light, thin, short, and small ones. In the prior art, a plurality of electronic elements is mainly carried on a circuit board, these electronic elements are electrically connected to each other, and the circuit board is configured in a case to gain protection for itself as well as the electronic elements. However, the appearances of the electronic products are limited by the shapes and sizes of the circuit boards, so that most of the electronic products are in the shape of a flat-panel and other three-dimensional shapes are rarely found.

Therefore, in order to directly form, for example, signal lines on a circuit board, on a three-dimensional element to replace a conventional circuit board, a concept of three-dimensional molded interconnect device (MID) emerges as required. Under this concept, electronic and mechanical functions are integrated on a three-dimensional element, thus changing the long-term impression on “plane” printed circuit boards. The MID technology may save space within the case, and further microminiaturize the electronic products.

US Patent Publication No. 2007/0247822 discloses a printed circuit structure and a method thereof. In the method, a non-conductive high-molecular composite material having special ingredients (non-conductive aluminum nitride contained in high-molecular material) is processed by laser, and then metallized by immersion. However, such a special material is high in cost and cannot be widely applied. What's worse, the above laser processing has to manufacture circuit patterns under special spectra and apertures, and is unable to effectively manufacture fine circuits on uneven surfaces. Therefore, it is still in need of a further breakthrough.

### SUMMARY OF THE INVENTION

Accordingly, the present invention is directed to a method for manufacturing a three-dimensional circuit. The method is adapted to form a three-dimensional circuit on a three-dimensional insulating structure, instead of on a conventional circuit board.

In order to specifically describe the content of the present invention, a method for manufacturing a three-dimensional circuit is provided and described as follows. Firstly, a three-dimensional insulating structure having at least one uneven surface is provided. Secondly, a self-assembly film is formed on the uneven surface for completely covering the uneven surface. Next, a catalytic film is formed on the self-assembly film. Afterward, the self-assembly film and the catalytic film are patterned. Then, a three-dimensional circuit structure is formed on the catalytic film by chemical deposition.

In an embodiment of the present invention, the three-dimensional insulating structure is made of plastic or ceramic.

In an embodiment of the present invention, a method for patterning the self-assembly film and the catalytic film includes laser ablation.

In an embodiment of the present invention, a method for patterning the self-assembly film and the catalytic film includes lithographic method.

In an embodiment of the present invention, a method for forming the self-assembly film includes immersion, spraying, or deposition.

In an embodiment of the present invention, a method for forming the three-dimensional insulating structure includes injection molding.

In order to specifically describe the content of the present invention, a method for manufacturing a three-dimensional circuit is provided and described as follows. Firstly, a three-dimensional insulating structure having at least one uneven surface is provided. Secondly, a patterned self-assembly film is formed on the uneven surface for partially covering the uneven surface. Then, a patterned catalytic film is formed on the patterned self-assembly film. Afterward, a three-dimensional circuit structure is formed on the patterned catalytic film by chemical deposition.

In an embodiment of the present invention, the three-dimensional insulating structure is made of plastic or ceramic.

In an embodiment of the present invention, a method for forming the patterned self-assembly film includes inkjet printing.

In an embodiment of the present invention, a method for forming the three-dimensional insulating structure includes injection molding.

In an embodiment of the present invention, a method for forming the patterned catalytic film includes inkjet printing.

Further, a method for manufacturing a three-dimensional circuit is provided and described as follows. Firstly, a three-dimensional insulating structure having at least one uneven surface is provided. Secondly, a self-assembly film is formed on the uneven surface for completely covering the uneven surface. Next, a catalytic film is formed on the self-assembly film. Afterward, a conductive layer is formed on the catalytic film. Then, a patterned anti-plating layer is formed on the conductive layer. The patterned anti-plating layer has at least one opening for exposing a portion of the conductive layer. A three-dimensional circuit structure is formed by electroplating on the portion of the conductive layer exposed out of the opening. After that, the patterned anti-plating layer, the conductive layer below the patterned anti-plating layer, the catalytic film below the patterned anti-plating layer, and the self-assembly film below the patterned anti-plating layer are removed, so as to form a patterned conductive layer, a patterned catalytic film, and a patterned self-assembly film.

In an embodiment of the present invention, a method for forming the conductive layer includes chemical deposition.

In an embodiment of the present invention, the three-dimensional insulating structure is made of plastic, ceramic, or glass.

In an embodiment of the present invention, a method for forming the three-dimensional insulating structure includes injection molding.

In view of the above, according to the present invention, a three-dimensional circuit can be formed on an uneven surface of a three-dimensional insulating structure, instead of on a conventional circuit board. Therefore, in the present invention, a three-dimensional circuit can be formed on various insulating objects, for example, directly formed on a case. In this manner, the appearances of electronic products are no longer limited by the shapes and volumes of the circuit boards, such that the design flexibility of the appearances of the electronic products is greatly improved, and the sizes thereof are also reduced.

In order to make the foregoing and other objectives, features, and advantages of the present invention comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1D are schematic cross-sectional views of a process for manufacturing a three-dimensional circuit according to an embodiment of the present invention.

FIGS. 2A to 2C are schematic cross-sectional views of a process for manufacturing a three-dimensional circuit according to an embodiment of the present invention.

FIGS. 3A to 3D are schematic cross-sectional views of a process for manufacturing a three-dimensional circuit according to an embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

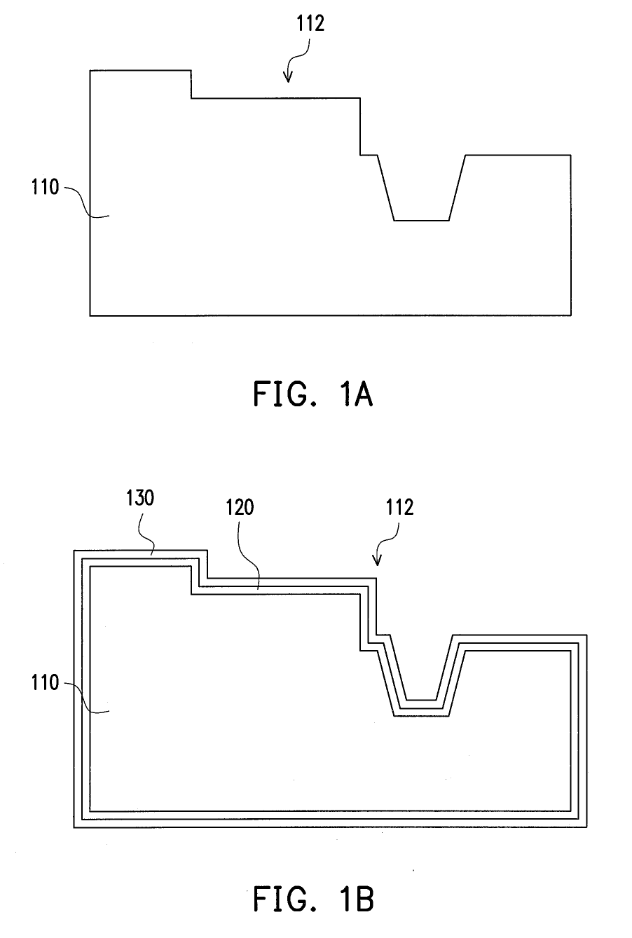

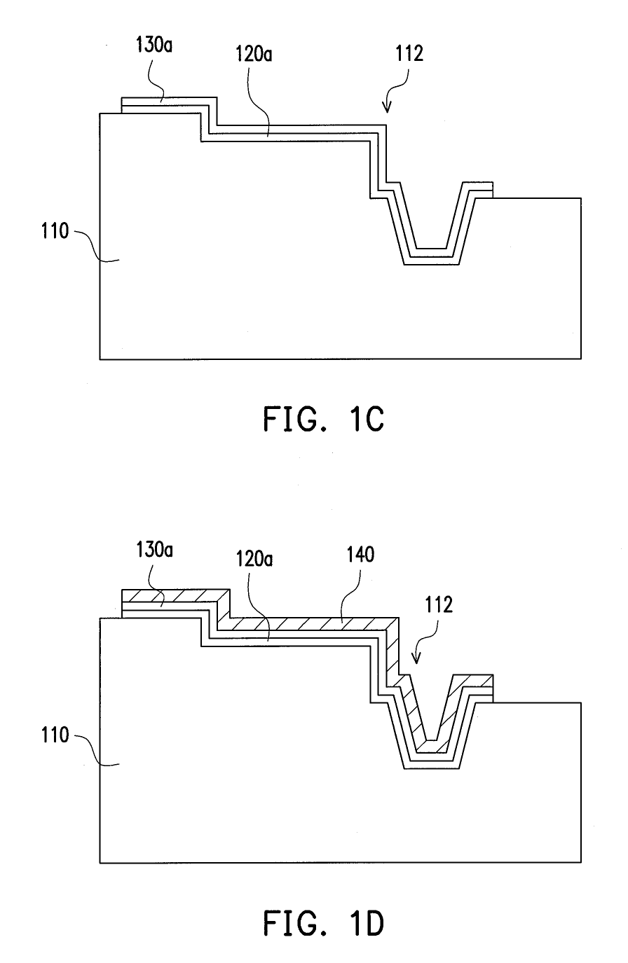

FIGS. 1A to 1D are schematic cross-sectional views of a process for manufacturing a three-dimensional circuit according to an embodiment of the present invention.

First, referring to FIG. 1A, a three-dimensional insulating structure 110 having an uneven surface 112 is provided as a substrate of a three-dimensional circuit structure to be formed later. It should be noted that, the uneven surface 112 in this embodiment generally refers to all kinds of uneven surfaces, such as a cambered surface, a surface with particles or protrusions, a surface with grooves, or a combination of the above.

In this embodiment, the three-dimensional insulating structure 110 is, for example, made of plastic, ceramic, or other suitable insulating materials. The three-dimensional insulating structure 110 may be an inflexible object such as a case, a bearing, a support column, a roller, a ball, a jig, a button, or a lighting fixture. When the three-dimensional insulating structure 110 is a plastic article such as a case or a button, the three-dimensional insulating structure 110 is, for example, formed by injection molding.

In other embodiments, the three-dimensional insulating structure 110 is, for example, a fabric made of cotton threads, yarns, nylon threads, or other suitable threads. The three-dimensional insulating structure 110 may be a flexible object such as a cloth, a watchband, or a hand ring.

Next, referring to FIG. 1B, a self-assembly film 120 is formed on the uneven surface 112 for completely covering the uneven surface 112. A method for forming the self-assembly film 120 includes immersion, spraying, deposition, or other methods suitable for fully contacting the uneven surface with a plating solution of the self-assembly film 120.

When the self-assembly film 120 is formed by immersion, the method is described in detail as follows. First, in Step 1, the three-dimensional insulating structure 110 is immersed in an anionic polyelectrolyte solution. The anionic polyelectrolyte solution is, for example, 10 mM poly(acrylic acid) (PAA). Next, in Step 2, the three-dimensional insulating structure 110 is washed with deionized water. Afterward, in Step 3, the three-dimensional insulating structure 110 is immersed in a cationic polyelectrolyte solution. The cationic polyelectrolyte solution is, for example, 10 mM poly(allylamine hydrochloride) (PAH). Then, in Step 4, the three-dimensional insulating structure 110 is again immersed in the anionic polyelectrolyte solution.

In this embodiment, the self-assembly film 120 can be formed by the above Steps 1 to 4, so as to achieve a surface modification effect of the uneven surface 112 of the three-dimensional insulating structure 110. In addition, different anionic polyelectrolyte solutions and cationic polyelectrolyte solutions can be selected in accordance with the three-dimensional insulating structure 110 of various materials.

Then, again referring to FIG. 1B, a catalytic film 130 is formed on the self-assembly film 120. A method for forming the catalytic film 130 includes immersion, spraying, deposition, or other methods suitable for fully contacting the self-assembly film 120 with a plating solution of the catalytic film 130. In this embodiment, the plating solution of the catalytic film 130 includes disodium tetrachloropalladate (Na₂PdCl₄) solution, tetraamminepalladium dichloride (Pd(NH₃)₄Cl₂) solution, or other suitable salt solutions. Moreover, metallic catalysts such as palladium can be precipitated after the solvent in the plating solution of the catalytic film 130 volatilizes.

Afterward, referring to FIG. 1C, the self-assembly film 120 and the catalytic film 130 are patterned so as to form a patterned self-assembly film 120a and a patterned catalytic film 130a. The self-assembly film 120 and the catalytic film 130 are patterned by, for example, laser ablation. In addition, the self-assembly film 120 and the catalytic film 130 may also be patterned by lithographic method. Then, a three-dimensional circuit structure 140 is formed on the patterned catalytic film 130a by chemical deposition, as shown in FIG. 1D. The chemical deposition is, for example, a chemical copper deposition.

It should be noted that, different from the prior art that circuits may only be formed on circuit boards or even surfaces, in this embodiment, the three-dimensional circuit structure 140 is formed on the uneven surface 112 of the three-dimensional insulating structure 110, instead of on a conventional circuit board. Therefore, in this embodiment, a three-dimensional circuit can be formed on various insulating objects, for example, directly formed on a case. In this manner, the appearances of electronic products are no longer limited by the shapes and volumes of the circuit boards, such that the design flexibility of the appearances of the electronic products is greatly improved, and the electronic products are further microminiaturized. Alternatively, for an electronic product, a part of the circuits can be formed on a circuit board, and the rest of the circuits can be formed on a three-dimensional insulating structure (for example, the case of the electronic product), such that the area of the circuit board is reduced and thus the volume of the electronic product is lowered.

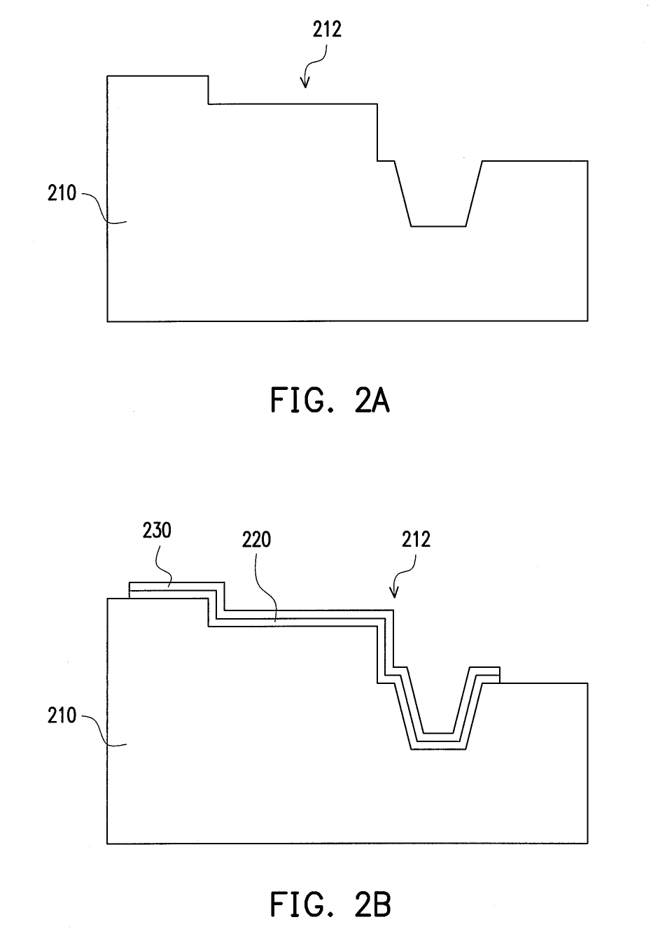

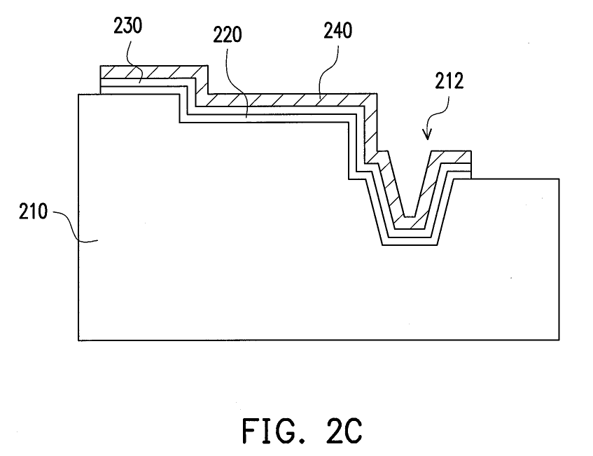

FIGS. 2A to 2C are schematic cross-sectional views of a process for manufacturing a three-dimensional circuit according to an embodiment of the present invention.

First, referring to FIG. 2A, a three-dimensional insulating structure 210 having an uneven surface 212 is provided as a substrate of a three-dimensional circuit structure to be formed later. It should be noted that, the uneven surface 212 in this embodiment generally refers to all kinds of uneven surfaces, such as a cambered surface, a surface with particles or protrusions, a surface with grooves, or a combination of the above. The material and usage of the three-dimensional insulating structure 210 are the same as those in the above embodiment, and the details will not be described herein again.

Next, referring to FIG. 2B, a patterned self-assembly film 220 is formed on the uneven surface for partially covering the uneven surface 212. In this embodiment, the patterned self-assembly film 220 is directly formed by inkjet printing. Then, a patterned catalytic film 230 is formed on the patterned self-assembly film 220. The patterned catalytic film 230 is formed by, for example, inkjet printing, and the material of the patterned catalytic film 230 includes salts. Afterward, a three-dimensional circuit structure 240 is formed on the patterned catalytic film 230 by chemical deposition, as shown in FIG. 2C.

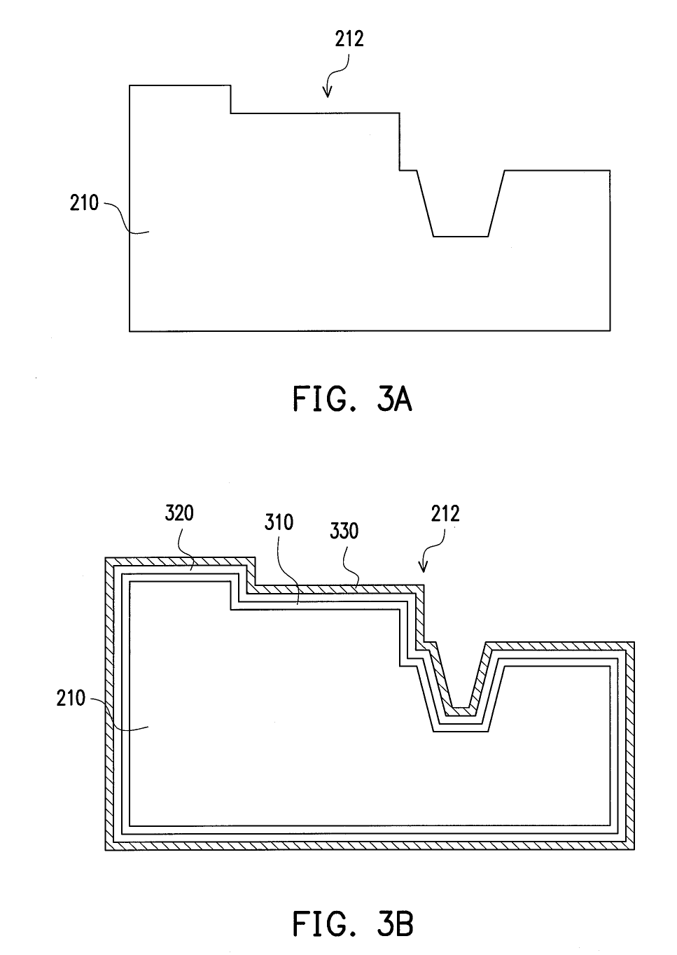

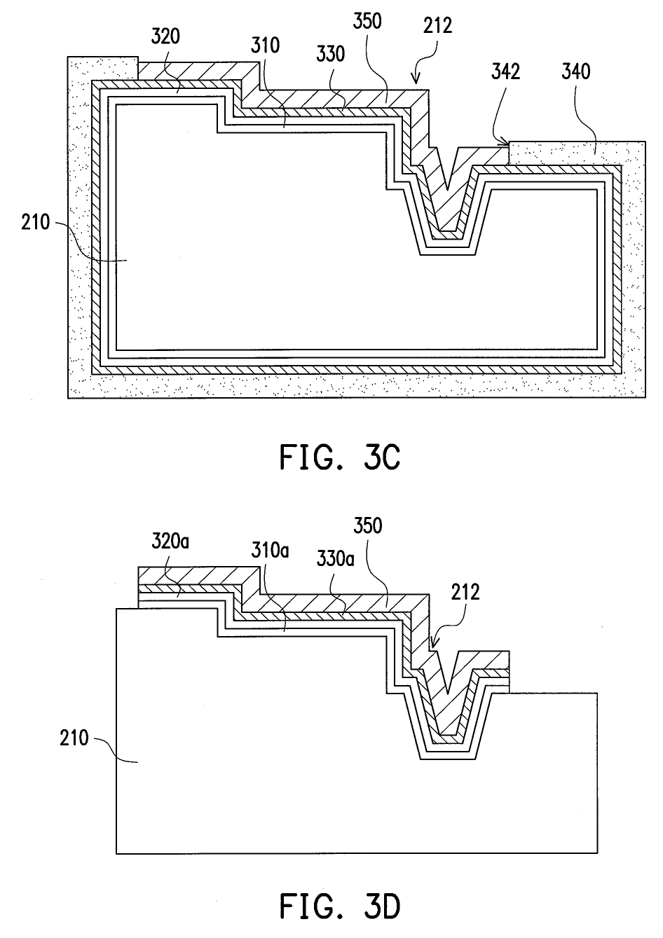

FIGS. 3A to 3D are schematic cross-sectional views of a process for manufacturing a three-dimensional circuit according to an embodiment of the present invention.

First, referring to FIG. 3A, a three-dimensional insulating structure 210 having an uneven surface 212 is provided as a substrate of a three-dimensional circuit structure to be formed later. Next, a self-assembly film 310 is formed on the uneven surface for completely covering the uneven surface 112, as shown in FIG. 3B. Then, a catalytic film 320 is formed on the self-assembly film 310. Afterward, a conductive layer 330 is formed on the catalytic film 320. The conductive layer 330 may be formed by chemical deposition or other suitable methods. The chemical deposition is, for example, a chemical copper deposition.

Next, referring to FIG. 3C, a patterned anti-plating layer 340 is formed on the conductive layer 330. The patterned anti-plating layer 340 has an opening 342 for exposing a portion of the conductive layer 330. A three-dimensional circuit structure 350 is then formed by electroplating on the portion of the conductive layer 330 exposed out of the opening 342. It should be noted that, compared to the prior art, the three-dimensional circuit structure 350 can be quickly formed by electroplating in this embodiment.

Afterward, the patterned anti-plating layer 340, the conductive layer 330 below the patterned anti-plating layer 340, the catalytic film 320 below the patterned anti-plating layer 340, and the self-assembly film 310 below the patterned anti-plating layer 340 are removed, so as to form a patterned conductive layer 330a, a patterned catalytic film 320a, and a patterned self-assembly film 310a, as shown in FIG. 3D.

In view of the above, in the present invention, a three-dimensional circuit can be formed on an uneven surface of a three-dimensional insulating structure, instead of on a conventional circuit board. Therefore, in the present invention, a three-dimensional circuit can be formed on various insulating objects, for example, directly formed on a case. In this manner, the appearances of electronic products are no longer limited by the shapes and volumes of the circuit boards, such that the design flexibility of the appearances of the electronic products is greatly improved, and the electronic products are further microminiaturized. Alternatively, for an electronic product, a part of the circuits can be formed on a circuit board, and the rest of the circuits can be formed on a three-dimensional insulating structure (for example, the case of the electronic product), such that the area of the circuit board is reduced and thus the volume of the electronic product is lowered.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for manufacturing a three-dimensional circuit, comprising:
providing a three-dimensional insulating structure comprising at least one uneven surface;
forming a self-assembly film on the uneven surface for completely covering the uneven surface;
forming a catalytic film on the self-assembly film;
patterning the self-assembly film and the catalytic film; and
forming a three-dimensional circuit structure on the catalytic film by chemical deposition.

2. The method for manufacturing a three-dimensional circuit according to claim 1, wherein the three-dimensional insulating structure is made of plastic, ceramic, or glass.

3. The method for manufacturing a three-dimensional circuit according to claim 1, wherein a method for patterning the self-assembly film and the catalytic film comprises laser ablation.

4. The method for manufacturing a three-dimensional circuit according to claim 1, wherein a method for patterning the self-assembly film and the catalytic film comprises lithographic method.

5. The method for manufacturing a three-dimensional circuit according to claim 1, wherein a method for forming the self-assembly film comprises immersion, spraying, or deposition.

6. The method for manufacturing a three-dimensional circuit according to claim 1, wherein a method for forming the three-dimensional insulating structure comprises injection molding.

7. A method for manufacturing a three-dimensional circuit, comprising:
providing a three-dimensional insulating structure comprising at least one uneven surface;
forming a patterned self-assembly film on the uneven surface for partially covering the uneven surface;
forming a patterned catalytic film on the patterned self-assembly film; and
forming a three-dimensional circuit structure on the patterned catalytic film by chemical deposition.

8. The method for manufacturing a three-dimensional circuit according to claim 7, wherein the three-dimensional insulating structure is made of plastic, ceramic, or glass.

9. The method for manufacturing a three-dimensional circuit according to claim 7, wherein a method for forming the patterned self-assembly film comprises inkjet printing.

10. The method for manufacturing a three-dimensional circuit according to claim 7, wherein a method for forming the three-dimensional insulating structure comprises injection molding.

11. The method for manufacturing a three-dimensional circuit according to claim 7, wherein a method for forming the patterned catalytic film comprises inkjet printing.

12. A method for manufacturing a three-dimensional circuit, comprising:
providing a three-dimensional insulating structure comprising at least one uneven surface;
forming a self-assembly film on the uneven surface for completely covering the uneven surface;
forming a catalytic film on the self-assembly film;
forming a conductive layer on the catalytic film;
forming a patterned anti-plating layer on the conductive layer, wherein the patterned anti-plating layer comprises at least one opening for exposing a portion of the conductive layer;
forming a three-dimensional circuit structure by electroplating on the portion of the conductive layer exposed out of the opening; and
removing the patterned anti-plating layer, the conductive layer below the patterned anti-plating layer, the catalytic film below the patterned anti-plating layer, and the self-assembly film below the patterned anti-plating layer, so as to form a patterned conductive layer, a patterned catalytic film, and a patterned self-assembly film.

13. The method for manufacturing a three-dimensional circuit according to claim 12, wherein a method for forming the conductive layer comprises chemical deposition.

14. The method for manufacturing a three-dimensional circuit according to claim 12, wherein the three-dimensional insulating structure is made of plastic, ceramic, or glass.

15. The method for manufacturing a three-dimensional circuit according to claim 12, wherein a method for forming the three-dimensional insulating structure comprises injection molding.
